(19) United States
(12) Patent Application Publication
(10) Pub. No.: US 2026/0311792 A1
(43) Pub. Date: Oct. 8, 2026

(54) MULTIPLE INPUT SIGNATURE REGISTER CIRCUIT WITH PASS-GATE EXCLUSIVE OR LOGIC

(71) Applicant: Micron Technology, Inc., Boise, ID (US)

(72) Inventors: Yong-jae LEE, Suwanee, GA (US); Tyler J. GOMM, Boise, ID (US)

(21) Appl. No.: 19/534,122

(22) Filed: Feb. 9, 2026

Related U.S. Application Data
(60) Provisional application No. 63/784,726, filed on Apr. 7, 2025.

(51) Int. Cl. G11C 29/46; G11C 29/12

(52) U.S. Cl. CPC G11C 29/46; G11C 29/12015

(57) ABSTRACT

In some implementations, an apparatus may include a built-in self-test circuit and a multiple input signature register (MISR) circuit. The built-in self-test circuit may be configured to implement a self-test of the apparatus and the MISR circuit may be configured to collect a set of results associated with the self-test. Additionally, the MISR circuit may include one or more pass-gate exclusive OR (XOR) logic gates.

### CROSS-REFERENCE TO RELATED APPLICATION

This Patent Application claims priority to U.S. Provisional Patent Application No. 63/784,726, filed on Apr. 7, 2025, entitled “MULTIPLE INPUT SIGNATURE REGISTER CIRCUIT WITH PASS-GATE EXCLUSIVE OR LOGIC,” and assigned to the assignee hereof. The disclosure of the prior Application is considered part of and is incorporated by reference into this Patent Application.

### TECHNICAL FIELD

The present disclosure generally relates to memory devices, memory device operations, and, for example, multiple input signature register (MISR) circuits.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system that includes a multiple input signature register (MISR) circuit with pass-gate XOR (exclusive OR) logic.

FIG. 2 is a diagram illustrating an example of a memory device that includes a MISR circuit with pass-gate XOR logic.

FIGS. 3A, 3B, AND 3C are diagrams illustrating example MISR circuits.

FIG. 4 is a diagram illustrating an example pass-gate XOR logic gate.

FIG. 5 is a flowchart of an example method associated with a MISR circuit that includes pass-gate XOR logic.

### DETAILED DESCRIPTION

Some memory systems or memory devices may employ built-in self-tests to improve a reliability of the memory system or memory device. In particular, a memory device may include built-in self-test circuitry that enables the memory device to test the operation and functionality of the memory device autonomously, which may improve a reliability of data stored by the memory device and detect faults associated with the memory device. In some cases, the built-in self-test circuitry may use a MISR circuit during a self-test of the memory device. MISR circuits typically perform one or more linear feedback shift register (LFSR) calculations to generate test patterns. The built-in self-test circuitry may analyze the test patterns generated by the MISR circuit to ensure that the memory device is operating correctly.

The MISR circuit may introduce a delay into the built-in self-test of the memory device. That is, the MISR circuit may be associated with a propagation delay corresponding to an amount of time required for the MISR circuit to generate an output signal (e.g., a test pattern) after receiving an input signal. In some cases, the MISR circuit may include one or more exclusive OR (XOR) logic gates, which may be associated with a relatively large amount of propagation delay (e.g., as compared to one or more other types of logic gates within the MISR circuit). This added delay may impact the speed at which the MISR circuit generates test patterns, which may in turn increase a delay associated with performing a built-in self-test of the memory device. Moreover, the area and power consumption of XOR logic gates within a MISR circuit may negatively impact the overall design efficiency and power consumption of the memory device.

Some implementations described herein provide an apparatus that includes a MISR circuit that utilizes a pass-gate XOR logic gate. The pass-gate XOR logic gate may be associated with a single-gate propagation delay, which is faster than the propagation delay of a standard XOR logic gate. Additionally, the pass-gate XOR logic gate may be associated with decreased area and power consumption, as compared to the standard XOR logic gate. The pass-gate XOR logic gate may be associated with a variable propagation delay and signal strength output based on the input to the pass-gate XOR logic gate. However, the variations in propagation delay and signal strength may not affect the reliability of the MISR circuitry performance. Additionally, even with the variable propagation delay, the overall speed associated with the MISR circuitry may still be reduced as compared to the speed associated with MISR circuitry that includes standard XOR logic gates. Accordingly, including the pass-gate XOR logic gate within the MISR circuit (e.g., as opposed to the standard XOR logic gate) may decrease the propagation delay associated with MISR circuit, decrease the power consumption of the MISR circuit, and reduce the layout area of the MISR circuit.

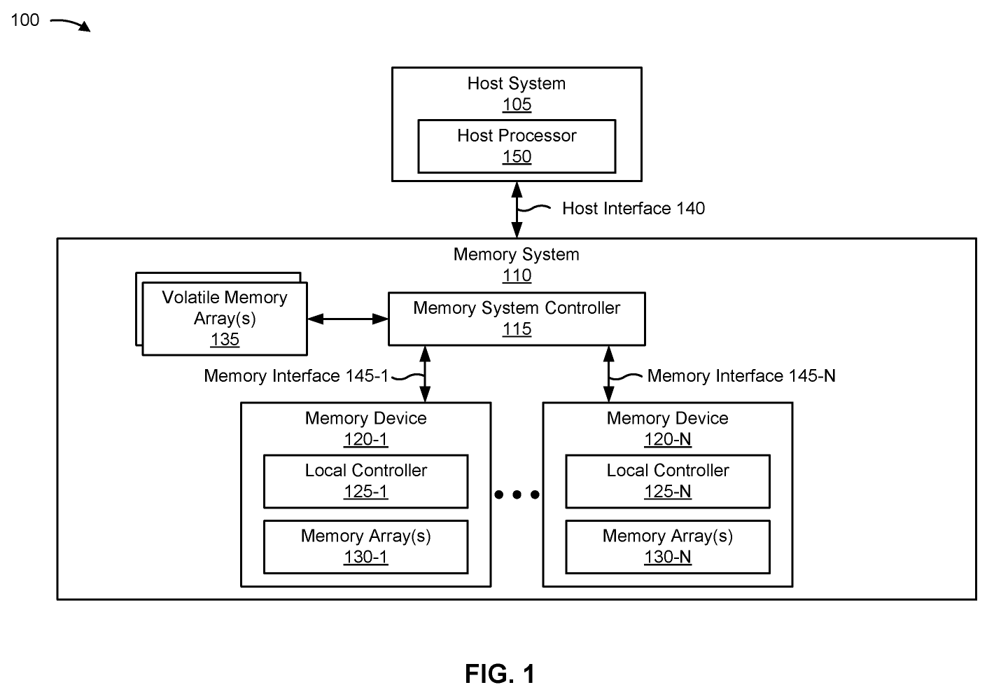

FIG. 1 is a diagram illustrating an example system 100 that includes a MISR circuit with pass-gate XOR logic. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N ≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N ≥ 1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more of the memory devices 120 may include a built-in self-test circuit coupled to a MISR circuit. The built-in self-test circuit may be configured to implement a self-test of the memory device; and the MISR circuit may comprise a pass-gate XOR logic gate and be configured to collect a set of results associated with the self-test.

In some implementations, one or more systems, devices, apparatuses, components, and/or controllers of FIG. 1 may be configured to initiate a built-in self-test of a memory device 120; and perform, using a plurality of logic gates comprising at least a pass-gate XOR logic gate, a MISR calculation based at least in part on initiating the built-in self-test.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

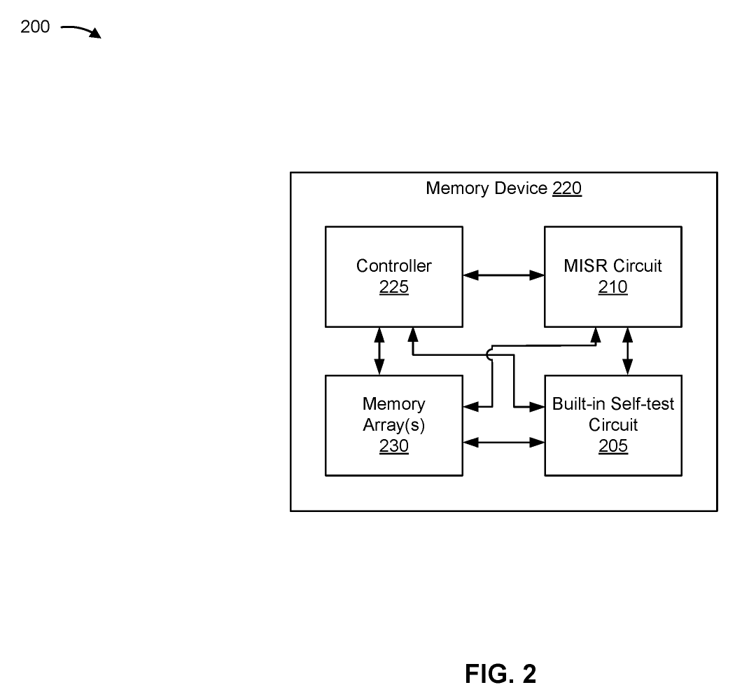

FIG. 2 is a diagram illustrating an example 200 of a memory device 220 that includes a MISR circuit 210 with pass-gate XOR logic. The example 200 may include aspects of the system 100 described with reference to FIG. 1. For example, the controller 225 may be an example of or include aspects of the local controller 125, and the memory arrays 230 may be an example of or include aspects of the memory arrays 130.

The memory device 220 may include a built-in self-test circuit 205. The built-in self-test circuit 205 may be configured to perform a built-in self-test of the memory device 220. To perform a built-in self-test, the built-in self-test circuit 205 may perform one or more diagnostic tests on one or more components of the memory device 220, monitor the responses of the one or more diagnostic tests, and analyze the results to identify and diagnose faults or errors associated with the one or more components of the memory device 220. Accordingly, performing the built-in self-test may improve the reliability and operation of the memory device 220 without relying on external testing equipment. While the example 200 illustrates the built-in self-test circuit 205 as being independent from the controller 225, in some other examples, the built-in self-test circuit 205 may be included within the controller 225.

The built-in self-test circuit 205 may initiate a built-in self-test of the memory device 220 according to a configured periodicity. For example, the memory device 220 may be configured (e.g., by the controller 225, by a memory system controller external to the memory device 220) to perform the built-in-self-test of the memory device 220 periodically. Additionally, or alternatively, the built-in self-test circuit 205 may initiate the built-in self-test of the memory device 220 in response to a trigger. For example, the built-in self-test circuit 205 may initiate the built-in self-test in response to the memory device 220 initially powering on. Additionally, the built-in self-test circuit 205 may initiate the built-in self-test based on receiving a command (e.g., from a controller of the memory system that is external to the memory device 220, from a host system) indicating for the memory device 220 to perform the built-in self-test. Additionally, the built-in self-test circuit 205 may initiate the built-in self-test based on detecting an error condition (e.g., in response to detecting more than a threshold quantity of errors within data stored by a memory array 230 of the memory device).

The memory device 220 may additionally include a MISR circuit 210. In some cases, the MISR circuit 210 may include a linear feedback shift register (LFSR), where bits are shifted through the MISR circuit 210 in response to receiving additional inputs. During a built-in self-test, the MISR circuit 210 may generate a signature, and the built-in self-test circuit 205 may determine whether the memory device 220 is operating correctly (or if there are any errors or faults associated with one or more components of the memory device 220) based on the signature generated by the MISR circuit 210.

The MISR circuit 210 may also include one or more XOR logic gates. A standard type of XOR logic gate may include a series of complementary metal-oxide-semiconductor (CMOS) transistors arranged to perform the exclusive OR function, and may be associated with a two-gate propagation delay. The two-gate propagation delay may be associated with a signal, to pass through the standard type of XOR logic gate, passing through two logic gates to generate an output, which may correspond to a delay in propagating the signal through the standard XOR logic gate. Additionally, a pass-gate XOR logic gate may include a combination of pass-gates and inverters. The pass-gate XOR logic gate may be associated with a one-gate propagation delay (e.g., a single-gate propagation delay). That is, to pass through the pass-gate XOR logic gate, the signal may pass through one logic gate (e.g., only a single logic gate) to generate the output. Accordingly, the delay associated with propagating a signal through a pass-gate XOR logic gate may correspond to a single-gate propagation delay.

In the example 200, the MISR circuit 210 may include one or more pass-gate XOR logic gates. As a result, the propagation delay of a signal through the MISR circuit 210 may be based on the signal passing through one or more pass-gate XOR logic gates associated with a single-gate propagation delay. Accordingly, the propagation delay of a signal through the MISR circuit 210 may be reduced as compared to MISR circuits 210 that include any standard XOR logic gates (e.g., that are associated with a two-gate propagation delay).

As indicated above, FIG. 2 is provided as an example. Other examples may differ from what is described with regard to FIG. 2.

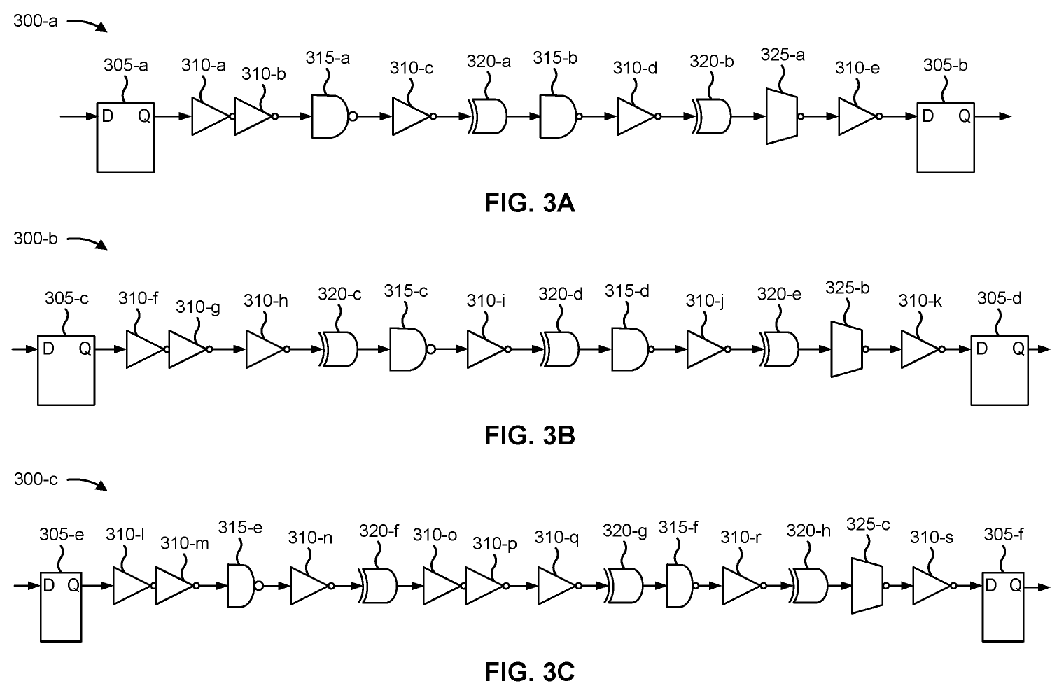

FIGS. 3A, 3B, AND 3C are diagrams illustrating example MISR circuits 300-a, 300-b, and 300-c, respectively. In some cases, the memory devices 120 or the memory device 220 may include the MISR circuit 300-a, the MISR circuit 300-b, or the MISR circuit 300-c. The MISR circuit 300-a, the MISR circuit 300-b, and the MISR circuit 300-c may include flip-flops 305, inverters 310, not AND (NAND) logic gates 315, XOR logic gates 320, and a multiplexer 325.

For example, the MISR circuit 300-a illustrated by FIG. 3A may include a first flip-flop 305-a at an input of the MISR circuit 300-a and a second flip-flop 305-b at an output of the MISR circuit 300-a. The MISR circuit 300-a may additionally include five inverters: inverter 310-a, inverter 310-b, inverter 310-c, inverter 310-d, and inverter 310-e; two NAND logic gates: NAND logic gate 315-a and NAND logic gate 315-b; two XOR logic gates: XOR logic gate 320-a and XOR logic gate 320-b; and one multiplexer 325-a.

In another example, illustrated in FIG. 3B, the MISR circuit300-b may include a first flip-flop 305-c at an input of the MISR circuit 300-b and a second flip-flop 305-d at an output of the MISR circuit 300-b. The MISR circuit 300-b may additionally include six inverters: inverter 310-f, inverter 310-g, inverter 310-h, inverter 310-i, inverter 310-j, and inverter 310-k; two NAND logic gates: NAND logic gate 315-c and NAND logic gate 315-d; three XOR logic gates: XOR logic gate 320-c, XOR logic gate 310-d, and XOR logic gate 320-e; and one multiplexer 325-b.

In another example, illustrated in FIG. 3C, the MISR circuit 300-c may include a first flip-flop 305-e at an input of the MISR circuit 300-c and a second flip-flop 305-f at an output of the MISR circuit 300-c. The MISR circuit 300-c may additionally include eight inverters: inverter 310-l, inverter 310-m, inverter 310-n, inverter 310-o, inverter 310-p, inverter 310-q, inverter 310-r, and inverter 310-s; two NAND logic gates: NAND logic gate 315-e and NAND logic gate 315-f; three XOR logic gates: XOR logic gate 320-f, XOR logic gate 310-g, and XOR logic gate 320-h; and one multiplexer 325-c.

In some cases, the MISR circuit 300-a, the MISR circuit 300-b, and the MISR circuit 300-c may include pass-gate XOR logic gates. That is, the MISR circuit 300-a may include two pass-gate XOR logic gates (e.g., the XOR logic gate 320-a and the XOR logic gate 320-b), the MISR circuit 300-b may include three pass-gate XOR logic gates (e.g., the XOR logic gate 320-c, the XOR logic gate 320-d, and the XOR logic gate 320-e), and the MISR circuit 300-c may include three pass-gate XOR logic gates (e.g., the XOR logic gate 320-f, the XOR logic gate 320-g, and the XOR logic gate 320-h).

The MISR circuit 300-a, the MISR circuit 300-b, and the MISR circuit 300-c may be faster (e.g., associated with a smaller propagation delay) as compared to similar MISR circuits that include standard XOR logic gates. In some cases, the increase in speed (e.g., and decrease in propagation delay) may be proportional to the quantity of XOR logic gates 320 within the MISR circuit 300. That is, the MISR circuits 300 with more XOR logic gates 320 (e.g., the MISR circuit 300-b and the MISR circuit 300-c) may be associated with larger speed improvements as compared to MISR circuits 300 with fewer XOR logic gates 320 (e.g., the MISR circuit 300-a).

Additionally, the MISR circuit 300-a, the MISR circuit 300-b, and the MISR circuit 300-c may have a smaller footprint as compared to similar MISR circuits that include standard XOR logic gates. That is, each pass-gate XOR logic gate may be associated with a smaller footprint as compared to a standard XOR logic gate. Accordingly, the MISR circuit 300-a, the MISR circuit 300-b, and the MISR circuit 300-c including pass-gate XOR logic gates (e.g., instead of standard XOR logic gates) may decrease the overall footprint of the MISR circuits 300. Further, the MISR circuit 300-a, the MISR circuit 300-b, and the MISR circuit 300-c may consume less power as compared to similar MISR circuits that include standard XOR logic gates. That is, each pass-gate XOR logic gate may consume less power as compared to a standard XOR logic gate. Accordingly, the MISR circuit 300-a, the MISR circuit 300-b, and the MISR circuit 300-c including pass-gate XOR logic gates (e.g., instead of standard XOR logic gates) may result in a decrease in power consumption of the MISR circuits 300.

As indicated above, FIG. 3 is provided as an example. Other examples may differ from what is described with regard to FIG. 3.

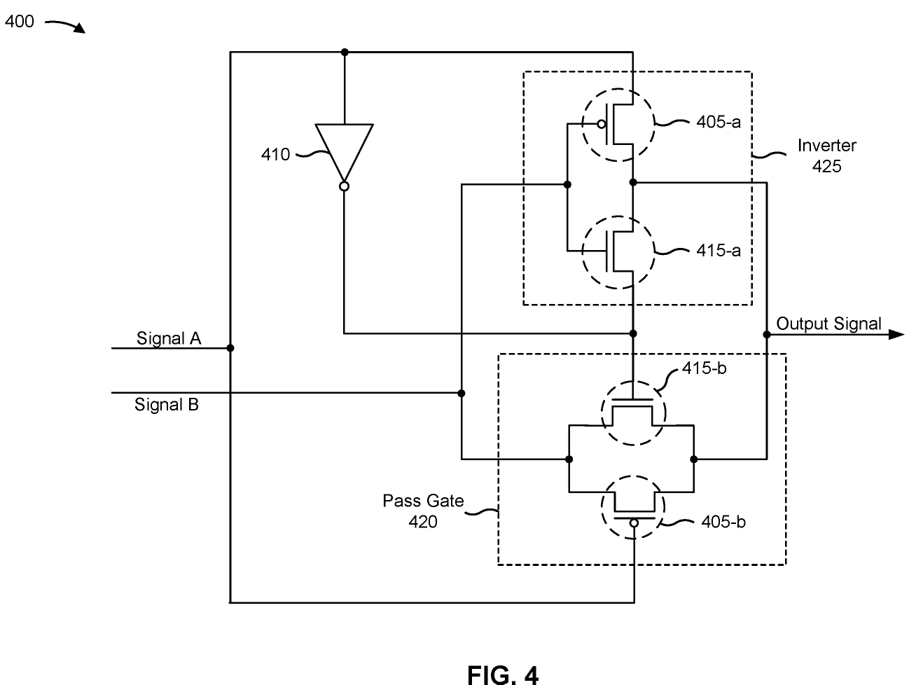

FIG. 4 is a diagram illustrating an example of pass-gate XOR logic gate 400. In some cases, the MISR circuit 210, the MISR circuit 300-a, the MISR circuit 300-b, and the MISR circuit 300-c may include at least one pass-gate XOR logic gate 400.

A signal A (e.g., an input signal) and a signal B (e.g., a preset signal) may be input to the pass-gate XOR logic gate 400, and the output signal may be generated (e.g., based on the signal A and the signal B). In some cases, the pass-gate XOR logic gate 400 may be associated with a single-gate propagation delay. That is, the delay between applying the signal A to the pass-gate XOR logic gate 400 and the pass-gate XOR logic gate 400 generating the output signal may correspond to a single-gate delay.

The pass-gate XOR logic gate 400 may include an inverter 410, two P-channel metal-oxide-semiconductor (PMOS) transistors 405-a and 405-b, and two N-channel metal-oxide-semiconductor (NMOS) transistors 415-a and 415-b. The PMOS transistor 405-b and the NMOS transistor 415-b may be arranged in a pass-gate configuration, and may form the pass gate 420. Additionally, the PMOS transistor 405-a and the NMOS transistor 415-a may be arranged in an inverter formation, and may form an inverter 425.

Based on the values of the signal A and the signal B, the signal A may follow a different propagation path through the pass-gate XOR logic gate 400. That is, the pass-gate XOR logic gate 400 may include two propagation paths: one path through the inverter 425 and a second path through the pass gate 420. In some cases, the propagation delay associated with the first and second propagation paths may be different. That is, the propagation delay associated with the first propagation path (e.g., through the inverter) may be less than the propagation delay associated with the second propagation path (e.g., through the pass gate 420). Accordingly, the propagation delay associated with the pass-gate XOR logic gate 400 may be different based on the values of the signal A and the signal B.

Additionally, the two propagation paths may also be associated with different output signal strengths. That is, the signal strength of the output signal when the output signal is propagated through the first propagation path (e.g., that includes the inverter 425) is greater than the signal strength of the output signal when the output signal is propagated through the second propagation path (e.g., that includes the pass gate 420). Accordingly, the strength of the output signal may be different based on whether the propagation path of the signal A includes the inverter 425 or the pass-gate 420.

As indicated above, FIG. 4 is provided as an example. Other examples may differ from what is described with regard to FIG. 4.

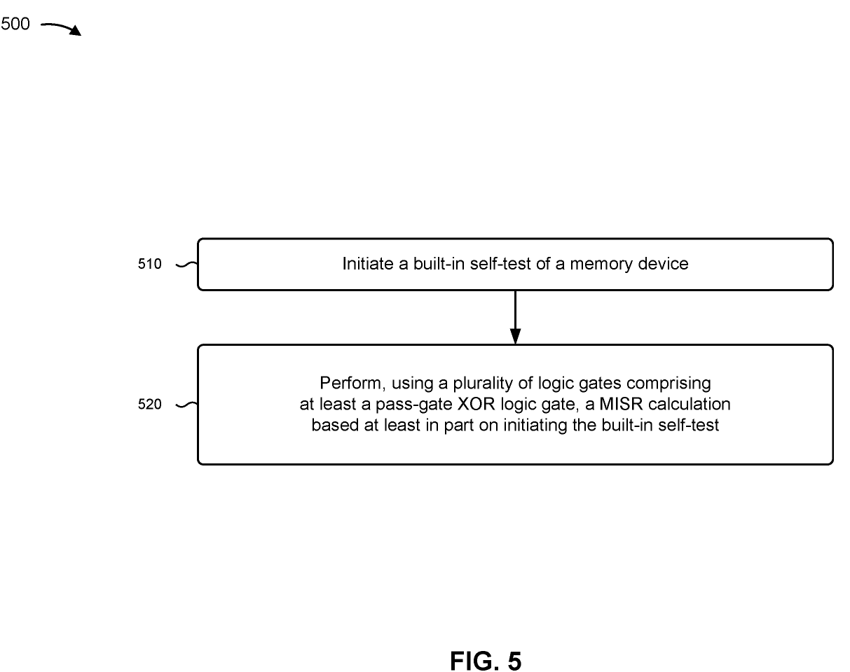

FIG. 5 is a flowchart of an example method 500 associated with a MISR circuit that includes pass-gate XOR logic. In some implementations, a memory device (e.g., the memory device 120, the memory device 220) may perform or may be configured to perform the method 500. In some implementations, another device or a group of devices separate from or including the memory device (e.g., the system 100) may perform or may be configured to perform the method 500. Additionally, or alternatively, one or more components of the memory device (e.g., the memory system controller 115, the local controller 125, the controller 225, the built-in self-test circuit 205, the MISR circuit 210) may perform or may be configured to perform the method 500. Thus, means for performing the method 500 may include the memory device and/or one or more components of the memory device. Additionally, or alternatively, a non-transitory computer-readable medium may store one or more instructions that, when executed by the memory device (e.g., the local controller 125 of the memory device 120), cause the memory device to perform the method 500.

As shown in FIG. 5, the method 500 may include initiating a built-in self-test of a memory device (block 510). As further shown in FIG. 5, the method 500 may include performing, using a plurality of logic gates comprising at least a pass-gate XOR logic gate, a MISR calculation based at least in part on initiating the built-in self-test (block 520).

The method 500 may include additional aspects, such as any single aspect or any combination of aspects described below and/or described in connection with one or more other methods or operations described elsewhere herein.

In a first aspect, the pass-gate XOR logic gate is associated with a single-gate propagation delay.

In a second aspect, alone or in combination with the first aspect, the MISR calculation is associated with a variable propagation delay that is based at least in part on a propagation path through the pass-gate XOR logic gate.

In a third aspect, alone or in combination with one or more of the first and second aspects, the variable propagation delay comprises a first propagation delay associated with a first propagation path through the pass-gate XOR logic gate, and a second propagation delay associated with a second propagation path through the pass-gate XOR logic gate.

In a fourth aspect, alone or in combination with one or more of the first through third aspects, the first propagation delay is based at least in part on the first propagation path comprising an inverter, and the second propagation delay is based at least in part on the second propagation path comprising a pass-gate.

In a fifth aspect, alone or in combination with one or more of the first through fourth aspects, the first propagation delay is less than the second propagation delay.

In a sixth aspect, alone or in combination with one or more of the first through fifth aspects, the MISR calculation is associated with a variable signal strength output based at least in part on a propagation path through the pass-gate XOR logic gate.

In a seventh aspect, alone or in combination with one or more of the first through sixth aspects, the variable signal strength output comprises a first signal strength output associated with a first propagation path through the pass-gate XOR logic, or a second signal strength output associated with a second propagation path through the pass-gate XOR logic.

In an eighth aspect, alone or in combination with one or more of the first through seventh aspects, the first signal strength output is based at least in part on the first propagation path comprising an inverter, and the second signal strength output is based at least in part on the second propagation path comprising a pass-gate.

In a ninth aspect, alone or in combination with one or more of the first through eighth aspects, the first signal strength output is larger than the second signal strength output.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

In some implementations, an apparatus includes a built-in self-test circuit coupled to a MISR circuit and configured to implement a self-test of the apparatus; and the MISR circuit comprising a pass-gate XOR logic gate and configured to collect a set of results associated with the self-test.

In some implementations, a method includes initiating a built-in self-test of a memory device; and performing, using a plurality of logic gates comprising at least a pass-gate XOR logic gate, a MISR calculation based at least in part on initiating the built-in self-test.

In some implementations, an apparatus includes means for initiating a built-in self-test of a memory device; and means for performing, using a plurality of logic gates comprising at least a pass-gate XOR logic gate, a MISR calculation based at least in part on initiating the built-in self-test.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
a built-in self-test circuit coupled to a multiple input signature register (MISR) circuit and configured to implement a self-test of the apparatus; and
the MISR circuit comprising a pass-gate exclusive OR (XOR) logic gate and configured to collect a set of results associated with the self-test.

2. The apparatus of claim 1, wherein the pass-gate XOR logic gate within the MISR circuit is associated with a single-gate propagation delay.

3. The apparatus of claim 1, wherein the pass-gate XOR logic gate within the MISR circuit is associated with a variable propagation delay based at least in part on an input to the pass-gate XOR logic gate.

4. The apparatus of claim 3, wherein the variable propagation delay comprises:
a first propagation delay associated with a first propagation path through the pass-gate XOR logic gate; and
a second propagation delay associated with a second propagation path through the pass-gate XOR logic gate.

5. The apparatus of claim 4, wherein:
the first propagation path comprises an inverter within the pass-gate XOR logic gate; and
the second propagation path comprises a pass-gate within the pass-gate XOR logic gate.

6. The apparatus of claim 4, wherein the first propagation delay is less than the second propagation delay.

7. The apparatus of claim 1, wherein the pass-gate XOR logic gate within the MISR circuit is associated with a variable signal strength output based at least in part on an input to the pass-gate XOR logic gate.

8. The apparatus of claim 7, wherein the variable signal strength output comprises:
a first signal strength output associated with a first propagation path through the pass-gate XOR logic; or
a second signal strength output associated with a second propagation path through the pass-gate XOR logic.

9. The apparatus of claim 8, wherein:
the first propagation path comprises an inverter within the pass-gate XOR logic gate; and
the second propagation path comprises a pass-gate within the pass-gate XOR logic gate.

10. The apparatus of claim 8, wherein the first signal strength output is larger than the second signal strength output.

11. A method, comprising:
initiating a built-in self-test of a memory device; and
performing, using a plurality of logic gates comprising at least a pass-gate exclusive OR (XOR) logic gate, a multiple input signature register (MISR) calculation based at least in part on initiating the built-in self-test.

12. The method of claim 11, wherein the pass-gate XOR logic gate is associated with a single-gate propagation delay.

13. The method of claim 11, wherein the MISR calculation is associated with a variable propagation delay that is based at least in part on a propagation path through the pass-gate XOR logic gate.

14. The method of claim 13, wherein the variable propagation delay comprises:
a first propagation delay associated with a first propagation path through the pass-gate XOR logic gate; and
a second propagation delay associated with a second propagation path through the pass-gate XOR logic gate.

15. The method of claim 14, wherein:
the first propagation delay is based at least in part on the first propagation path comprising an inverter; and
the second propagation delay is based at least in part on the second propagation path comprising a pass-gate.

16. The method of claim 14, wherein the first propagation delay is less than the second propagation delay.

17. The method of claim 11, wherein the MISR calculation is associated with a variable signal strength output based at least in part on a propagation path through the pass-gate XOR logic gate.

18. The method of claim 17, wherein the variable signal strength output comprises:
a first signal strength output associated with a first propagation path through the pass-gate XOR logic; or
a second signal strength output associated with a second propagation path through the pass-gate XOR logic.

19. The method of claim 18, wherein:
the first signal strength output is based at least in part on the first propagation path comprising an inverter; and
the second signal strength output is based at least in part on the second propagation path comprising a pass-gate.

20. The method of claim 18, wherein the first signal strength output is larger than the second signal strength output.

21. An apparatus, comprising:
means for initiating a built-in self-test of a memory device; and
means for performing, using a plurality of logic gates comprising at least a pass-gate exclusive OR (XOR) logic gate, a multiple input signature register (MISR) calculation based at least in part on initiating the built-in self-test.

22. The apparatus of claim 21, wherein the pass-gate XOR logic gate is associated with a single-gate propagation delay.

23. The apparatus of claim 21, wherein the MISR calculation is associated with a variable propagation delay that is based at least in part on a propagation path through the pass-gate XOR logic gate.

24. The apparatus of claim 23, wherein the variable propagation delay comprises:
a first propagation delay associated with a first propagation path through the pass-gate XOR logic gate; and
a second propagation delay associated with a second propagation path through the pass-gate XOR logic gate.

25. The apparatus of claim 21, wherein the MISR calculation is associated with a variable signal strength output based at least in part on a propagation path through the pass-gate XOR logic gate.
